(19) United States
(12) Patent Application Publication
(10) Pub. No.: US 2007/0007630 A1
(43) Pub. Date: Jan. 11, 2007

(54) Switching element for a pixel electrode and methods for fabricating the same

(75) Inventors: Kuo-Lung Fang, Jhudong Township (TW); Wen-Ching Tsai, Wujie Township (TW); Kuo-Yuan Tu, Toufen Township (TW); Han-Tu Lin, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/345,090

(22) Filed: Feb. 1, 2006

(30) Foreign Application Priority Data
Jul. 7, 2005 (TW) 94122983

(51) Int. Cl. H01L 23/58

(52) U.S. Cl. 257/644

(57) ABSTRACT

The invention discloses a switching element for a pixel electrode of display device and methods for fabricating the same. A gate is formed on a substrate. A high-k dielectric layer is formed on the gate. The high-k dielectric layer comprises HfO₂, HfNO, HfSiO, HfSiNO, or HfAlO. A semiconductor layer is formed on the high-k dielectric layer. A source and a drain are formed on a portion of the semiconductor layer.

### BACKGROUND

The invention relates to a display device, and more particularly to a switching element for a pixel electrode and methods for fabricating the same.

In thin film transistors of a conventional LCD, SiNₓ or SiO₂ is typically utilized as a metal gate-insulating layer or a dielectric layer of a storage capacitor.

However, SiNₓ weakens the gate control and fails to provide enough capacitance due to its low dielectric constant of about 7. Additionally, the short-channel effect is induced.

U.S. Pat. No. 6,835,667 B2, the entirety of which is hereby incorporated by reference, describes a method of etching a high-k metal silicate film. The high-k metal silicate film comprises HfSiO₄, ZrSiO₄, or Hf_{0.6}Si_{0.4}O₂.

There is a continued need to provide a high-k dielectric material to increase storage capacitance of capacitor in TFT.

### SUMMARY

The invention provides thin film transistors and fabrication methods thereof capable of enhancing gate control and reducing short-channel effect.

A metal layer is formed on a substrate, for example, by chemical vapor deposition (CVD), electrochemical plating (ECP), or physical vapor deposition (PVD). The substrate 110 may be a glass substrate or a plastic substrate.

A metal gate is formed on the substrate after sequential photolithography and etching processes. The metal gate comprises Cu, Al, Ag, or metal alloy thereof, and the thickness thereof is substantially in a range of about 100 nm to 500 nm.

A high-k dielectric layer serving as a metal gate-insulating layer is conformally formed on the metal gate prior to formation of a semiconductor layer (not shown) on the metal gate-insulating layer. Methods of formation of the metal gate-insulating layer comprise CVD, or sputtering deposition. The metal gate-insulating layer comprises HfO₂, HfNO, HfSiO, HfSiNO, or HfAlO. The thickness of metal gate-insulating layer is substantially in a range of about 50 nm to about 500 nm.

In other embodiments, the metal gate-insulating layer may be a stacked structure of the described high-k dielectrics and SiNₓ, for example, HfO₂/SiNₓ, HfNO/SiNₓ, HfSiO/SiNₓ, HfSiNO/SiNₓ, or HfAlO/SiNₓ.

The semiconductor layer comprising a channel layer and an ohmic contact layer is defined on a portion of the metal gate-insulating layer by deposition and patterning. The channel layer can be an undoped amorphous silicon layer formed by CVD, and the thickness thereof is substantially in a range of about 50 nm to about 200 nm. The ohmic contact layer can be an impurity-added silicon layer formed by CVD, and the thickness thereof is substantially in a range of about 10 nm to about 100 nm. The impurity can be n type dopant (for example, P or As) or p type dopant (for example, B).

A metal layer is formed on the ohmic contact layer 150, for example, by CVD, electrochemical plating (ECP), or sputter deposition. The source/drain of metal are formed on the semiconductor layer by selectively etching through the metal layer and ohmic contact layer, exposing a portion of the surface of the channel layer. A pixel electrode is formed, electrically connecting to the source or the drain. As a result, a thin film transistor serving as a switching element is obtained. The source/drain comprise Cu, Ag, Al, or metal alloy thereof. The thickness of the source/drain is substantially in a range of about 100 nm to about 500 nm.

The high-k dielectrics utilized in the invention has a k vale greater than 7, preferably between 7 and 25.

Thin film transistors (TFTs) of the invention can be bottom-gate or top-gate type TFTs, serving as switching elements for a pixel electrode when the source/drain electrically contacts a pixel electrode. In addition, the TFTs of the invention can be applied in display such as an LCD.

### DESCRIPTION OF THE DRAWINGS

The invention can be more fully understood by reading the subsequent detailed description in conjunction with the examples and references made to the accompanying drawings.

FIGS. 1A to 1D are sectional views illustrating an exemplary process for fabricating an embodiment of a TFT structure of the present invention.

### DETAILED DESCRIPTION

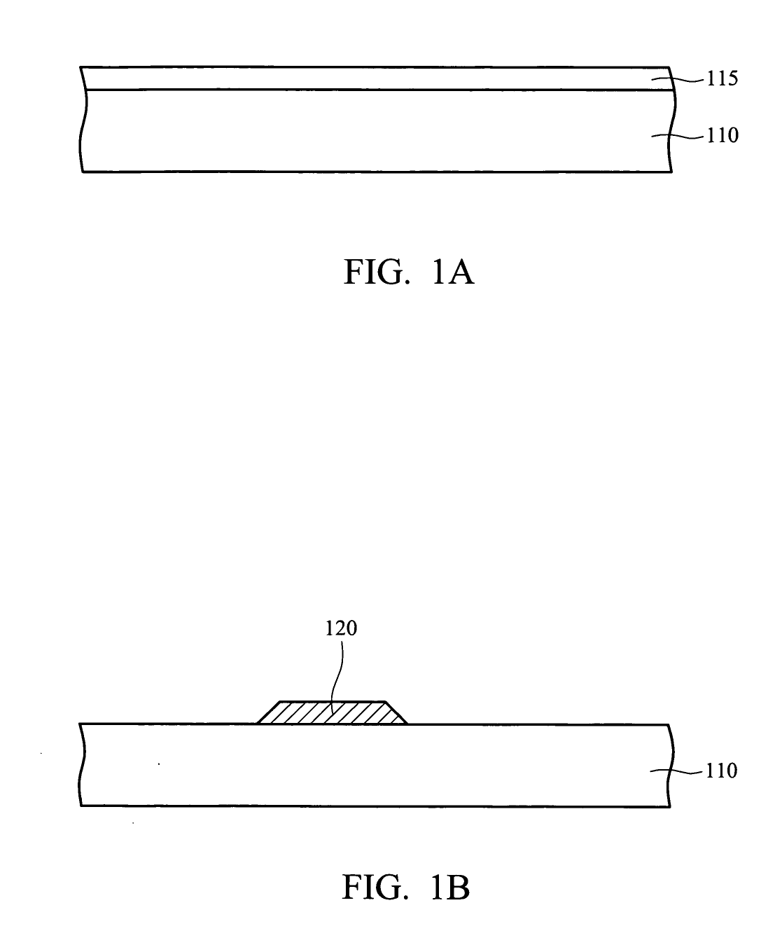

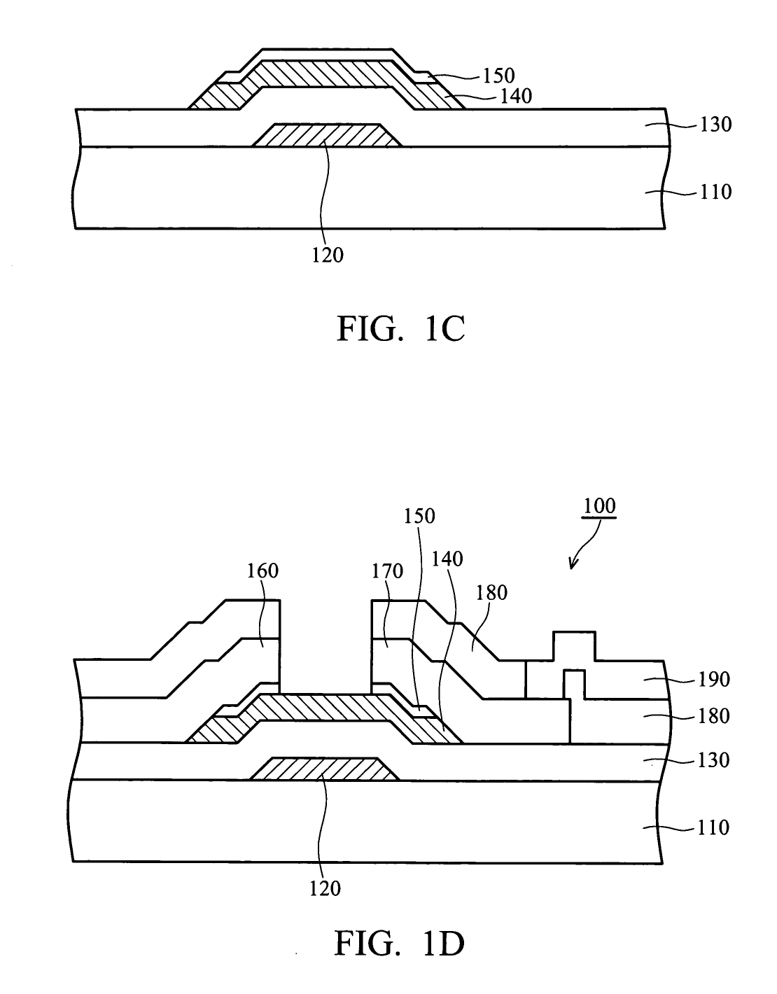

An exemplary process for fabricating TFTs of the invention is shown in FIGS. 1A-1D.

In FIG. 1A, a metal layer 115 is formed on a substrate 110, for example, by chemical vapor deposition (CVD), electrochemical plating (ECP), or physical vapor deposition (PVD). The substrate 110 may be a glass substrate or a plastic substrate. The metal layer 115 may comprise Cu, Al, Ag, or metal alloy thereof.

In FIG. 1B, a metal gate 120 is formed on the substrate 110 after sequential photolithography and etching processes. That is, a photoresist pattern (not shown) is formed on the metal layer 115 by photolithography. The metal layer 120 is then etched by wet etching or dry etching while using the photoresist pattern as the etching mask, thus, the metal gate 120 is formed. The thickness of the metal gate 120 is substantially in a range of about 100 nm to 500 nm.

In FIG. 1C, a high-k dielectric layer serving as a metal gate-insulating layer 130 is conformally formed on the metal gate 120 and the substrate 110 followed by formation of a semiconductor layer (not shown) on the metal gate-insulating layer 130. Methods of formation of the metal gate-insulating layer 130 comprise CVD, or sputter deposition. The metal gate-insulating layer 130 comprises HfO₂, HfNO, HfSiO, HfSiNO, or HfAlO. The thickness of metal gate-insulating layer 130 is substantially in a range of about 50 nm to about 500 nm. In other embodiments, the metal gate-insulating layer 130 may be a stacked structure of the described high-k dielectrics and SiNₓ, for example, HfO₂/SiNₓ, HfNO/SiNₓ, HfSiO/SiNₓ, HfSiNO/SiNₓ, or HfAlO/SiNₓ.

The described semiconductor layer comprises an α—Si layer formed by chemical vapor deposition and an impurity-doped α—Si layer deposited by CVD thereon in sequence. The α—Si layer and the impurity-doped α—Si layer are defined by photolithography and etching to form a channel layer 140 and an ohmic contact layer 150. The semiconductor layer comprising a channel layer 140 and an ohmic contact layer 150 is defined on a portion of the metal gate-insulating layer 130 by deposition and patterning. The channel layer 140 can be an undoped amorphous silicon layer formed by CVD, and the thickness thereof is substantially in a range of about 50 nm to about 200 nm. The ohmic contact layer 150 can be an impurity-doped silicon layer formed by CVD, and the thickness thereof is substantially in a range of about 10 nm to about 100 nm. The impurity can be n type dopant (for example, P or As) or p-type dopant (for example, B).

In FIG. 1D, a metal layer (not shown) is formed on the ohmic contact layer 150 and the metal gate-insulating layer 130, for example, by CVD, electrochemical plating (ECP), or sputtering deposition. The metal layer may comprise Cu, Ag, Al, or metal alloy thereof. The source/drain 160/170 of metal are formed on the semiconductor layer by selectively etching through the metal layer and ohmic contact layer 150, exposing a portion of surface of the channel layer 140. That is, a photoresist pattern (not shown) is formed on the metal layer by photolithography. The metal layer and the ohmic contact layer 150 is then etched by wet etching or dry etching to form the source/drain 160/170. A passivation layer 180 is formed prior to formation of a pixel electrode 190 electrically connected to the source 160 or the drain 170. As a result, a thin film transistor 100, serving as a switching element, is obtained. The thickness of the source/drain 160/170 is substantially in a range of about 100 nm to about 500 nm.

As described, replacement of a conventional silicon nitride layer with high-k dielectric layer serving as a metal gate dielectric layer facilitates gate control. The k value of the high-k dielectric layer is greater than 7, preferably between 7 and 25. Storage capacitance is also enhanced when the high-k dielectric layer is utilized in a capacitor.

Thin film transistors (TFTs) of the invention can be bottom-gate or top-gate TFTs, serving as switching elements for a pixel electrode when the source/drain electrically contacts a pixel electrode. In addition, the TFTs of the invention can be applied in display such as an LCD

While the invention has been described by way of example and in terms of preferred embodiments, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A switching element for a pixel electrode of a
display device, comprising:
a gate on a substrate;
a high-k dielectric layer on the gate, wherein the high-k dielectric layer comprises HfO₂, HfNO, HfSiO, HfSiNO, or HfAlO;
a semiconductor layer on the high-k dielectric layer; and
a source and a drain on a portion of the semiconductor layer.

2. The switching element of a pixel electrode according to claim 1, further comprising a pixel electrode electrically connected to the source or the drain.

3. The switching element of a pixel electrode according to claim 1, wherein the gate is covered with the high-k dielectric layer.

4. The switching element of a pixel electrode according to claim 1, wherein the substrate comprises a glass substrate or a plastic substrate.

5. The switching element of a pixel electrode according to claim 1, wherein the gate comprises Cu, Ag, Al, or metal alloy thereof.

6. The switching element of a pixel electrode according to claim 1, wherein the semiconductor layer comprises silicon.

7. The switching element of a pixel electrode according to claim 1, wherein the source/drain comprises Cu, Ag, Al, or metal alloy thereof.

8. The switching element of a pixel electrode according to claim 1, wherein the high-k dielectric layer is a gate-insulating layer.

9. A method of forming a switching element of a pixel electrode, comprising the steps of:
forming a gate on a substrate;
forming a high-k dielectric layer on the gate, wherein the high-k dielectric layer comprises HfO₂, HfNO, HfSiO, HfSiNO, or HfAlO;
forming a semiconductor layer on the high-k dielectric layer; and
forming a source and a drain on a portion of the semiconductor layer.

10. The method according to claim 9, further comprising forming a pixel electrode electrically connected to the source or the drain.

11. The method according to claim 9, wherein the gate is covered with the high-k dielectric layer.

12. The method according to claim 9, wherein the substrate comprises a glass substrate or a plastic substrate.

13. The method according to claim 9, wherein the gate comprises Cu, Ag, Al, or metal alloy thereof.

14. The method according to claim 9, wherein the semiconductor layer comprises silicon.

15. The method according to claim 9, wherein the source/drain comprise Cu, Ag, Al, or metal alloy thereof.

16. The method according to claim 9, wherein the high-k dielectric layer is a gate-insulating layer.

17. The method according to claim 9, wherein formation of the high-k dielectric layer comprises CVD or sputtering.
